(19) United States
(12) Patent Application Publication
(10) Pub. No.: US 2003/0058004 A1
(43) Pub. Date: Mar. 27, 2003

(54) Method and apparatus for direct digital synthesis of frequency signals

(76) Inventors: Robert E. Stengel, Pompano Beach, FL (US); Nicholas Giovanni Cafaro, Coconut Creek, FL (US)

Correspondence Address: MOTOROLA, INC, INTELLECTUAL PROPERTY SECTION, LAW DEPT, 8000 WEST SUNRISE BLVD, FT LAUDERDAL, FL, 33322, US

(21) Appl. No.: 09/961,940

(22) Filed: Sep. 24, 2001

(51) Int. Cl. H03B 21/00

(52) U.S. Cl. 327/105

(57) ABSTRACT

A frequency signal generator (300) generates a desired output signal Fₒᵤₜ (365) based on the ratio of the frequency a reference clock signal (301) to that of the desired output signal (F_{clk}/Fₒᵤₜ)=N+R, where the N is an integer portion and R is a fractional portion of the ratio. A counter (320) generates a counter overflow signal based on counting a minimum of N transitions of the reference clock signal. An accumulator (330) accumulates the fractional portion R in response to the counter overflow signal (325), and outputs the accumulated value (335) that is preferably used as address information for selecting one of a number of delay paths (340, 350) for outputting the desired output signal.

### TECHNICAL FIELD

This invention relates in general to synthesizers, and more particularly to time interpolating direct digital synthesis.

### BACKGROUND

Recently, direct digital synthesizers (DDS) based on time domain interpolation have emerged as an attractive option for frequency generation, particularly for wide bandwidth applications. For portable communication applications, implementations that have a low power consumption specification are particularly valuable. In one known approach, a reference clock signal is used to derive another frequency signal based on a relationship between both signals. An accumulator operating in response to the reference clock signal accumulates a digital value related to the relationship between the desired frequency signal and the reference clock signal until a maximum value is reached and an accumulator overflow occurs. The accumulator overflow is used to trigger the output of the desired frequency signal and the operation of any correction circuitry for perfecting the signal. The correction circuitry may include the use of a sine wave lookup table implemented in a read-only memory (ROM), which stores the sine trigonometric function, or may include the use of tapped delay lines. Attempts have been made to reduce the power consumption and complexity of various portions of this design. However, the requirements for low power consumption have not been adequately satisfied for some applications. Hence, a need exists for alternative designs that improve performance in the above-mentioned aspects, while maintaining or improving functionality.

### BRIEF DESCRIPTION OF THE DRAWINGS

The features of the present invention, which are believed to be novel, are set forth with particularity in the appended claims. The invention, together with further objects and advantages thereof, may best be understood by reference to the following description, taken in conjunction with the accompanying drawings, in the several figures of which like reference numerals identify like elements, and in which:

FIG. 1 shows a prior art digital synthesizer.

FIG. 2 shows a prior art direct digital synthesizer having a multiplier.

FIG. 3 shows a direct digital synthesizer in accordance with the preferred embodiment.

### DETAILED DESCRIPTION OF THE PREFERRED EMBODIMENT

While the specification concludes with claims defining the features of the invention that are regarded as novel, it is believed that the invention will be better understood from a consideration of the following description in conjunction with the drawing figures, in which like reference numerals are carried forward.

Generally, the present invention provides for a signal generator that directly synthesizes selected frequency signals based on the relationship of a desired frequency output signal to a reference clock signal. The signal generator relies on a clock signal source that provides a reference clock signal. A counter is coupled to the clock signal source and operates to generate a counter overflow signal based on counting a particular number of cycles of the reference clock signal. An accumulator accumulates a phase adjustment value and outputs the accumulated value in response to the counter overflow signal. The particular number of cycles counted by the counter and the phase adjustment value is preferably based upon a ratio of the frequency of the reference clock signal and the frequency of the desired output signal. In the preferred embodiment, the output of the accumulator is used as address information for selecting one of a number of delay lines, thereby implementing the necessary phase adjustment. The desired output signal is governed by the counter overflow signal and the selected delay line.

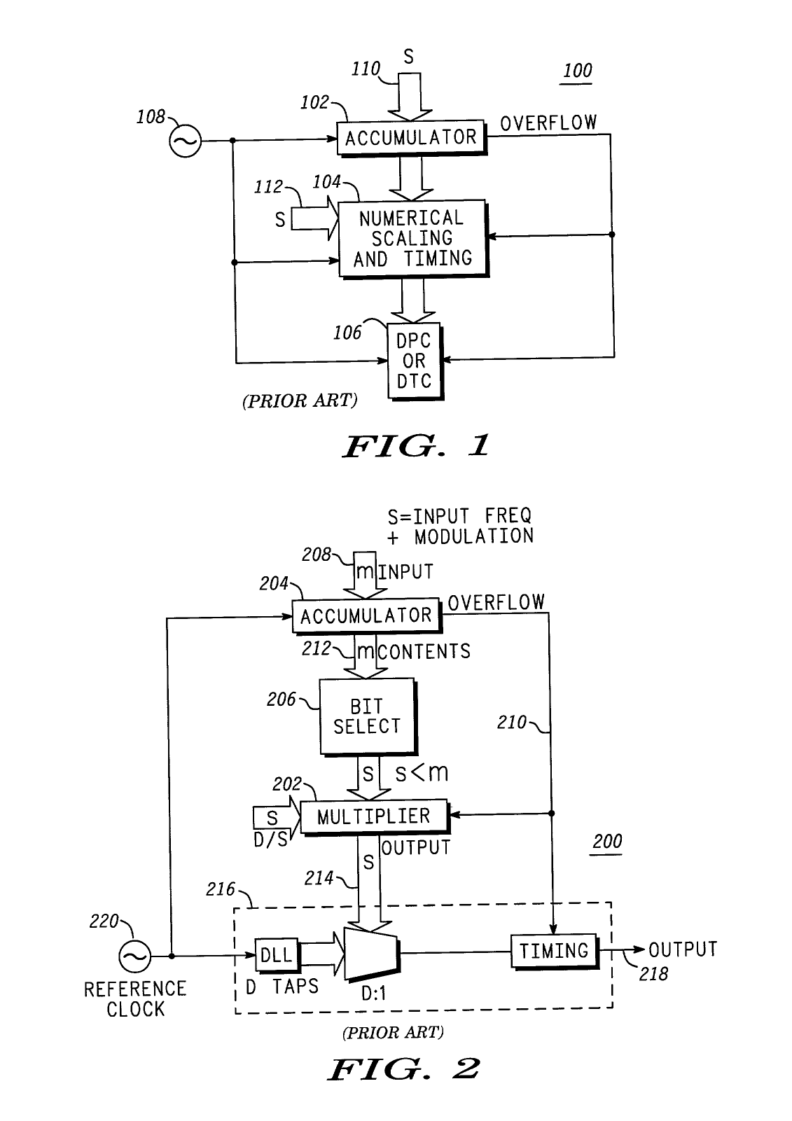

FIG. 1 shows a prior art synthesizer 100 which will be discussed for comparison purposes. Synthesizer 100 includes an accumulator 102 which has one input for receiving a signal (“S”) 110 representative of the required synthesizer output and an input for receiving a reference clock signal 108. The accumulator 102 also includes an overflow output for providing an overflow signal to a numerical scaling and timing block 104 and to a digital phase converter (DPC) or digital time converter (DTC) block 106. The numerical scaling and timing block 104 takes the content of the accumulator 102 and uses a signal 112 that is S or a function of S to scale it numerically. The numerical scaling and timing block 104 can also deal with signal timing issues. The DPC or DTC block 106 takes the numerical input from the numerical scaling block 104 and then it shifts the phase of the synthesizer's output signal according to that numerical input received. The DPC or DTC 106 can be constructed in a number of different ways as is well known in the art.

FIG. 2 shows a prior art synthesizer 200 that implements a particular example of a DPC block that incorporates tapped delay lines and delay lock loop (DLL) time interpolation. Here, a multiplier 202 numerically scales the contents of an accumulator 204 to determine which delay line tap to select. Synthesizer 200 includes an accumulator 204 that is a clocked m-bit structure with an “m” wide input bus 208. Accumulator 204 includes a single-bit overflow signal 210 and an m-bit contents bus 212. The input bus 208 receives a frequency select word, which is a representation of the input frequency plus any added modulation that sets the frequency of the output signal provided on output 218. The output signal on output 218 is a single-bit waveform.

A reference clock 220 provides a reference clock signal to the accumulator 204 and to a delay lock loop (DLL), while the multiplier 202 is clocked using the overflow signal 210. A bit selector 206 takes the m-bit wide contents output 212 and provides an s-bit (s<m) wide signal 214, which can take the form of a nominal tap value. The bit selector block 206 is necessary to properly truncate the m-bit wide contents 212 of the frequency accumulator 204 to s-bit wide for the multiplier 202. The s-bit wide signal 214 is provided to a tap selection block 216 which includes the DLL having a total of “D” number of taps.

For accumulator input “S” with value less than or equal to ½ the capacity, “C”, of accumulator 204 the average overflow output rate is equal to the output frequency of the synthesizer fₒᵤₜ. That is

fₒᵤₜ=f_{ref}(S/C)

The pulses at the accumulator overflow output 210 are, typically non-uniformly spaced in time. The remaining contents in the accumulator 204 during an overflow cycle can be interpreted as the fraction of a cycle of the output by which the overflow waveform needs to be shifted to produce uniformly spaced pulses. That is,

change in t_{i=T}_{ref}(Aᵢ/S)

where the change in tᵢ is the required time shift for the overflow pulse for clock cycle “i”, T_{ref} is the average period of the reference clock waveform, and Aᵢ is the contents of the accumulator on the ith cycle. The DLL is used to generate the delayed output pulse. The delay line has a total of “D” taps, and the total delay through the line is set to a whole number of reference clock periods. This delay can be set by the delay lock loop (DLL) in block 216 as shown, or using other delay structures.

A digital-to-phase converter 216 includes the DLL, a multiplexer that receives the s-bit wide contents of the multiplier 202 and a timing block. The digital phase converter 216 provides the synthesizer's output 218. The function of the digital-to-phase converter 216 is to shift the clock pulse applied at its clock input by the time-shift specified at its input port 214. In this context, a full scale value for the s-bit word at the digital-to-phase converter's input 214 is a full cycle phase shift of the reference clock 220. Note that for clock cycles of the reference clock 220 that no accumulator overflow is produced, no output is generated at the digital-to-phase converter output 218.

The accumulators 102, 204 and DPC or DTC modules 106, 216 are clocked by the reference clock signal. The digital logic and other circuitry that must be constantly active in these components represent a significant source of power consumption. The multiplier 202 used in the synthesizer FIG. 2 is another major consumer of power. The present invention provides for a synthesizer design that allows for significantly lower power consumption specifications.

FIG. 3 is a block diagram of a direct digital frequency synthesizer or signal generator 300 in accordance with the preferred embodiment of the present invention. The synthesizer 300 generates a derived frequency signal (Fₒᵤₜ) 365 from a reference clock signal (F_{clk}) 301 based on the relationship ratio (F_{clk}/Fₒᵤₜ)=N+R, where the N is an integer portion and R is a fractional portion of the ratio.

According to the invention, a counter 320 is coupled to the reference clock signal and operates to count cycles of the reference clock signal 301 and to generate a counter overflow signal 325 after counting a minimum of N cycles, where N is the integer portion of the above-mentioned ratio. A phase accumulator 330 is coupled to the counter 320 and has an input of a step value 303 equal to the fractional portion R of the above-mentioned ratio. The accumulator 330 accumulates the step value R in response to the counter overflow signal, i.e., each time the counter overflow signal is generated. The accumulator 330 generates an accumulator overflow signal 331 when accumulation of the fractional portion R results in an overflow of the accumulator.

In accordance with the present invention, the accumulator is further operated to increase the accuracy or resolution of the signal generator. Upon startup or reset, the accumulator is preloaded with an initial value 304 corresponding to a rounding factor. The rounding factor is based on the predetermined resolution of the accumulator. Preferably, for an accumulator in which the “p” most significant bits are used for addressing information, the rounding factor is determined by setting the (p+1)^{th} bit, the bit one less significant than the p most significant bits used for addressing. For example, in an 8-bit accumulator in which the first 4 bits are used for addressing purposes, the initial value is determined by setting the 5^{th} bit, i.e., the value in binary could be 00001000. The rounding effect is perpetuated throughout the frequency generation process without further action beyond the loading of the initial value. Accordingly, the accuracy of the accumulated fractional portion of the frequency of the reference signal represented by the contents of the accumulator is automatically increased without the use of complex hardware or signal processing.

In the preferred embodiment, the counter 320 uses rising edges of the reference clock signal for counting purposes. However, one skilled in the art would appreciate that other signal transitions could be used to trigger the counting mechanism. Based on this counting technique, the actual number of rising edges of the reference signal that is equivalent to a minimum of N cycles may be N or N+1. This determination may be based on the overflow status of the accumulator 330. Accordingly, a summer 310 is coupled to the counter 320 to provide the proper counter control input to the counter 320. The summer 310 has a first input of N 302 representing the required minimum number of cycles, and a second input coupled to the overflow signal output 331 from the accumulator. Preferably, the accumulator overflow signal 331 has a value of 0 when there is no accumulator overflow and a value of 1 when an accumulator overflow condition exists. The summer 310 sums both the first and second inputs and generates an output N′ 315 that forms the count control input of the counter 320.

The output of the accumulator 330 is used to trigger the output of the desired frequency signal Fₒᵤₜ, including the operation of any correction circuitry for perfecting the signal. In the preferred embodiment, the output of the accumulator is address information used to select one of a number of selectable delays for governing output of the desired frequency signal. The delay corresponds to the accumulated fractional portion of the reference signal, if any, that must be accounted for prior to outputting the desired output signal based on the established relationship between the frequency of the reference signal and the frequency of the desired output signal. Accordingly, the output 335 of the accumulator 330 is coupled to a delay block 370 that includes a tapped delay line 340 and a multiplexer 350. The tapped delay line 340 preferably includes a number of selectable delay lines, each operating to delay a signal by differing amounts of time. The delay block represents multiple delay paths, each being selectable by addressing the multiplexer 350. When a signal is sent through the delay block 370, the path taken by the signal through the delay block and hence the corresponding delay is governed by the addressing of the multiplexer. Thus, the delay block 370 is responsive to the address information outputted from the accumulator 330 to select one of the delay paths to govern output of the desired signal. The number of the delay lines or paths and the number of bits associated with the accumulator are both selected to effect a particular resolution for the signal generator 300.

The delay block 370 is preferably clocked by an output 326 from the counter, and in effect operates at or near the clock rate of the desired output signal. In the preferred embodiment, when the counter value is zero, a pulse is sent through the delay block, which ultimately forms the basis of the desired output signal Fₒᵤₜ. Ordinarily, the counter has a value of zero upon reset or immediately following an overflow of the counter. This corresponds with the output of address information 335 outputted from the accumulator 330 that operates to select the appropriate delay path through the delay block for the pulse. In this manner, the delay block is selectively enabled coincidentally with the output of address information from the accumulator and otherwise disabled in conjunction with a primary operating mode. The delay block is coupled to a duty cycle block 360 that conditions the pulse and outputs the desired signal 365. A reset signal line 305 is coupled to the summer 310, the counter 320, the accumulator 330, and the duty cycle block for reset purposes.

The present invention offers significant advantages over the prior art. For example, in a signal generator constructed accordingly, the counter operates at the frequency of the reference clock signal, and the summer, the accumulator, and the delay block all have an operating frequency equal to that of the desired output signal. This construction represents a significant savings in the power consumption requirements of the digital logic circuitry implementing these functions when compared to competing approaches.

While the preferred embodiments of the invention have been illustrated and described, it will be clear that the invention is not so limited. Numerous modifications, changes, variations, substitutions and equivalents will occur to those skilled in the art without departing from the spirit and scope of the present invention as defined by the appended claims.

We claim:

1. A signal generator responsive to a reference clock signal having a frequency F_{clk} to generate a desired signal having a frequency Fₒᵤₜ, the signal generator comprising:
a counter coupled to the reference clock signal and responsive thereto to generate a counter overflow signal based on counting a particular number of cycles of the reference clock signal, wherein the particular number of cycles is related to a relationship between the reference clock signal and the desired signal; and
an accumulator coupled to the counter and having an input of a step value related to a relationship between the reference clock signal and the desired signal, the accumulator being responsive to the counter overflow signal to output address information based on an accumulation of the step value for governing output of the desired signal.

2. The signal generator of claim 1, wherein the frequency of the desired signal Fₒᵤₜ and the frequency of the reference clock signal F_{clk} has a ratio (F_{clk}/Fₒᵤₜ)=N+R, where the N is an integer portion and R is a fractional portion of the ratio, and the counter operates to count a minimum of N cycles of the reference clock signal before generating the counter overflow signal.

3. The signal generator of claim 2, wherein:
the accumulator has an output of an accumulator overflow signal;
the counter is triggered by rising edges of the reference clock signal; and
the counter generates the counter overflow signal upon either of N or N+1 occurrences of rising edges of the reference clock signal depending on the accumulator overflow signal.

4. The signal generator of claim 3, further comprising a summer having a first input of N, and a second input coupled to the accumulator overflow signal, wherein the accumulator overflow signal has a value of 0 or 1 depending on an overflow status of the accumulator, and the summer provides an output of N or N+1 as a count control signal to the counter.

5. The signal generator of claim 4, wherein the summer has an operating frequency equal to that of the desired signal.

6. The signal generator of claim 4, wherein the accumulator has an operating frequency equal to that of the desired signal.

7. The signal generator of claim 1, further comprising a delay block having a plurality of delays for governing output of the desired signal, wherein the delay block is coupled to the accumulator and is responsive to the address information outputted therefrom to select one of the plurality of delays to govern output of the desired signal.

8. The signal generator of claim 7, wherein the delay block is selectively enabled coincidentally with the output of address information from the accumulator and otherwise disabled in conjunction with a primary operating mode.

9. The signal generator of claim 8, wherein the delay block is selectively enabled based on an output of the counter.

10. The signal generator of claim 1, wherein the accumulator has an input of a rounding factor for initialization purposes prior to the accumulation of the step value.

11. A method for generating a desired signal Fₒᵤₜ using a reference clock signal F_{clk}, wherein the desired signal Fₒᵤₜ and the reference clock signal F_{clk} has a relationship ratio (F_{clk}/Fₒᵤₜ)=N+R, where the N is an integer portion and R is a fractional portion of the ratio, the method comprising the steps of:
generating a counter overflow signal by counting at least N transitions of the reference clock signal;
accumulating the fractional portion R in response to the counter overflow signal to obtain an accumulated value; and
outputting, as the desired signal, a signal derived from the reference clock signal based on the counting of at least N transitions of the reference clock signal and adjusted for the fractional portion R using at least a portion of the accumulated value.

12. The method of claim 11, wherein the step of outputting comprises the steps of:
generating a pulse corresponding to the counting of at least N transitions of the reference clock signal; and
routing the pulse using a delay path selected based on address information derived from at least a portion of the accumulated value.

13. The method of claim 12, further comprising the step of reducing power consumption by disabling the delay path when not needed to process the pulse.

14. The method of claim 11, further comprising the step of initializing an accumulator with a rounding factor and utilizing the accumulator so initialized to accumulate the fractional portion R.

15. A method for generating a desired signal having a frequency Fₒᵤₜ using a reference clock signal having a frequency F_{clk}, wherein the frequency of the desired signal Fₒᵤₜ and the frequency of the reference clock signal F_{clk} has a relationship ratio (F_{clk}/Fₒᵤₜ)=N+R, where the N is an integer portion and R is a fractional portion of the ratio, the method comprising the steps of:
operating a counter to count transitions of the reference clock signal and to output a counter overflow signal based on a counter control value related to N;
operating an accumulator to accumulate the fractional portion R in response to the counter overflow signal to obtain an accumulated value; and
selecting a signal adjustment mechanism using at least a portion of the accumulated value;
generating an output signal based on a particular state of the counter; and
processing the output signal using the selected signal adjustment mechanism to obtain the desired signal.

16. The method of claim 15, wherein the step of selecting a signal adjustment mechanism comprises the step of enabling one of a plurality of delay paths, and the step of processing the output signal comprises the step of routing the output signal through the enabled delay path.

17. The method of claim 16, further comprising the step of reducing power consumption by enabling the plurality of delay paths when needed to process the output signal, and otherwise disabling the plurality of delay paths, according to a normal operating mode.

18. The method of claim 15, further comprising the step of initializing the accumulator with a rounding factor.

19. The method of claim 15, further comprising the step of setting the counter control value to N or N+1 depending on an overflow status of the accumulator.

20. A method utilizing an accumulator in signal processing, wherein the accumulator has n bits used for accumulation of which p most significant bits are used for output, comprising the steps of:
initializing the accumulator with a rounding factor value such that the p most significant bits are zero and at least one other bit is non-zero; and
operating the accumulator to accumulate an input value that adds to the rounding factor value.
